(19) United States
(12) Patent Application Publication
(10) Pub. No.: US 2026/0215187 A1
(43) Pub. Date: Jul. 23, 2026

(54) SUBSTRATE PROCESSING METHOD AND SUBSTRATE PROCESSING APPARATUS

(71) Applicant: Tokyo Electron Limited, Tokyo (JP)

(72) Inventor: Hitoshi KOSUGI, Kumamoto (JP)

(73) Assignee: Tokyo Electron Limited, Tokyo (JP)

(21) Appl. No.: 19/437,352

(22) Filed: Dec. 31, 2025

(30) Foreign Application Priority Data
Jan. 22, 2025 (JP) 2025-008934

(51) Int. Cl. H10P 50/66; H10P 70/00

(52) U.S. Cl. CPC H10P 50/667; H10P 70/27

(57) ABSTRACT

A substrate processing method includes treating a surface of a metallic film that includes ruthenium with a first processing liquid to form a metal chloride on a surface of the metallic film, and removing the metal chloride with a second processing liquid.

### CROSS-REFERENCE TO RELATED APPLICATION(S)

This application is based upon, and claims the benefit of priority to, Japanese Patent Application No. 2025-008934, filed on Jan. 22, 2025, the entire contents of which are herein incorporated by reference.

### FIELD

A disclosed embodiment(s) relate(s) to a substrate processing method and a substrate processing apparatus.

### BACKGROUND

In recent years, a need for miniaturization is increasingly grown in a fabrication step for a semiconductor device. For reacting to such a need, technology development of atomic layer etching (Atomic Layer Etching: ALE) is being advanced where a target substance is etched in the order of atomic layers. For example, a technique is disclosed to execute atomic layer etching for a metallic film that includes cobalt or copper in a wet process (see Japanese Patent Application Publication No. 2018-181984).

### SUMMARY

A substrate processing method according to an embodiment includes treating a surface of a metallic film that includes ruthenium with a first processing liquid to form a metal chloride on a surface of the metallic film, and removing the metal chloride with a second processing liquid.

### BRIEF DESCRIPTION OF DRAWING(S)

FIG. 1 is a schematic diagram that illustrates a general configuration of a substrate processing system according to an embodiment.

FIG. 2 is a schematic diagram that illustrates an example of a specific configuration of a processing unit according to an embodiment.

FIG. 3 is a flowchart that illustrates an example of a procedure of substrate processing according to an embodiment.

FIG. 4 is an enlarged cross-sectional diagram that illustrates an example of a state of a wafer surface after a preparation process according to an embodiment.

FIG. 5 is an enlarged cross-sectional diagram that illustrates an example of a state of a wafer surface after a chloride formation process according to an embodiment.

FIG. 6 is an enlarged cross-sectional diagram that illustrates an example of a state of a wafer surface after a chloride removal process according to an embodiment.

FIG. 7 is a diagram that illustrates a relationship between a number of times that a process is executed and etching thicknesses of various types of materials for substrate processing according to an embodiment.

### DESCRIPTION OF EMBODIMENT(S)

Hereinafter, an embodiment(s) of a substrate processing method and a substrate processing apparatus as disclosed in the present application will be explained in detail with reference to the accompanying drawing(s). Additionally, the present disclosure is not limited by an embodiment(s) as illustrated below. Furthermore, the drawing(s) is/are schematic where it should be noted that a relationship between dimensions of respective elements, a ratio of respective elements, etc., may be different from a reality. Moreover, parts with dimension relationships and/or ratios that are different from one another may be included among mutual drawings.

In recent years, a need for miniaturization is increasingly grown in a fabrication step for a semiconductor device. For reacting to such a need, technology development of atomic layer etching is being advanced where a target substance is etched in the order of atomic layers. For example, a technique is disclosed to execute atomic layer etching for a metallic film that includes cobalt or copper in a wet process.

On the other hand, a conventional technique as described above has room for further improvement in that atomic layer etching is efficiently executed for a metallic film that includes ruthenium where its application to a semiconductor device is being examined.

Hence, realization of a technique is expected that overcomes a problem(s) as mentioned above and is capable of executing atomic layer etching for a metallic film that includes ruthenium efficiently.

### Outline of Substrate Processing System

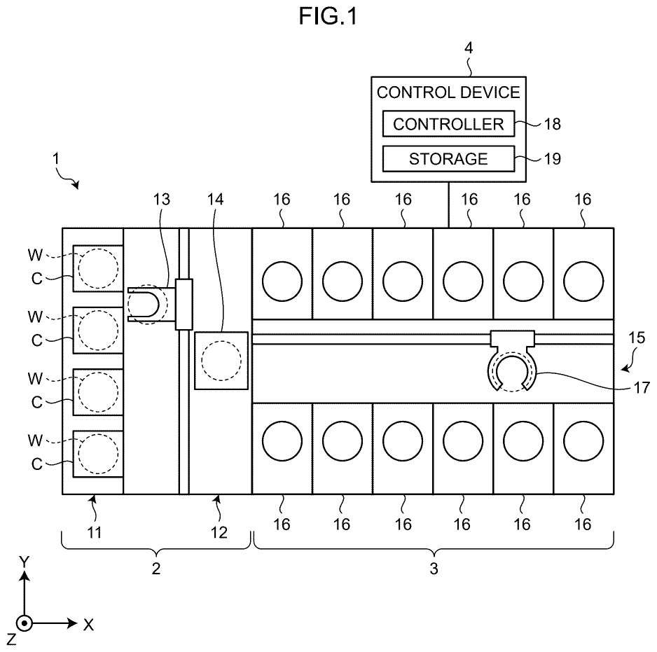

First, a general configuration of a substrate processing system 1 according to an embodiment will be explained with reference to FIG. 1. FIG. 1 is a schematic diagram that illustrates a general configuration of a substrate processing system 1 according to an embodiment. Hereinafter, an X-axis, a Y-axis, and a Z-axis that are orthogonal to one another are defined where a positive direction of such a Z-axis is a vertically upward direction, in order to clarify a positional relationship.

The substrate processing system 1 is an example of a substrate processing apparatus. As illustrated in FIG. 1, the substrate processing system 1 includes a carrying-in/out station 2 and a processing station 3. The carrying-in/out station 2 and the processing station 3 are provided adjacently.

The carrying-in/out station 2 includes a carrier placing section 11 and a transfer section 12. A plurality of carriers C that house a plurality of substrates, in an embodiment, semiconductor wafers W (that will be called wafers W below) in a horizontal state are placed in the carrier placing section 11.

The transfer section 12 is provided so as to be adjacent to the carrier placing section 11 and includes a substrate transfer device 13 and a delivery unit 14 in an inside thereof. The substrate transfer device 13 includes a wafer holding mechanism that holds a wafer W. Furthermore, the substrate transfer device 13 is capable of moving in a horizontal direction and a vertical direction and turning around a vertical axis as a center thereof, and executes transfer of a wafer W between a carrier C and the delivery unit 14 by using a wafer holding mechanism.

The processing station 3 is provided so as to be adjacent to the transfer section 12. The processing station 3 includes a transfer section 15 and a plurality of processing units 16. The plurality of processing units 16 are provided side by side on both sides of the transfer section 15.

The transfer section 15 includes a substrate transfer device 17 in an inside thereof. The substrate transfer device 17 includes a wafer holding mechanism that holds a wafer W. Furthermore, the substrate transfer device 17 is capable of moving in a horizontal direction and a vertical direction and turning around a vertical axis as a center thereof, and executes transfer of a wafer W between the delivery unit 14 and a processing unit 16 by using a wafer holding mechanism.

Such a processing unit 16 executes predetermined substrate processing for a wafer W that is transferred by the substrate transfer device 17.

Furthermore, the substrate processing system 1 includes a control device 4. The control device 4 is, for example, a computer, and includes a controller 18 and a storage 19. The storage 19 stores therein a program that controls various types of processes that are executed in the substrate processing system 1. The controller 18 reads and executes a program that is stored in the storage 19 so as to control an operation of the substrate processing system 1.

Additionally, such a program may have been recorded in a computer-readable storage medium and be installed on the storage 19 of the control device 4 from such a storage medium. For a computer-readable storage medium, for example, a hard disk (HD), a flexible disk (FD), a compact disk (CD), a magneto-optical disk (MO), a memory card, etc., are provided.

In the substrate processing system 1 configured as described above, first, the substrate transfer device 13 of the carrying-in/out station 2 takes a wafer W from a carrier C that is placed in the carrier placing section 11, and places such a taken wafer W on the delivery unit 14. Such a wafer W that is placed on the delivery unit 14 is taken from the delivery unit 14 and is carried in a processing unit 16, by the substrate transfer device 17 of the processing station 3.

Such a wafer W that is carried in such a processing unit 16 is processed by the processing unit 16, and subsequently, is carried out of the processing unit 16 and is placed on the delivery unit 14, by the substrate transfer device 17. Then, such a processed wafer W that is placed on the delivery unit 14 is returned to a carrier C in the carrier placing section 11, by the substrate transfer device 13.

### Configuration of Processing Unit

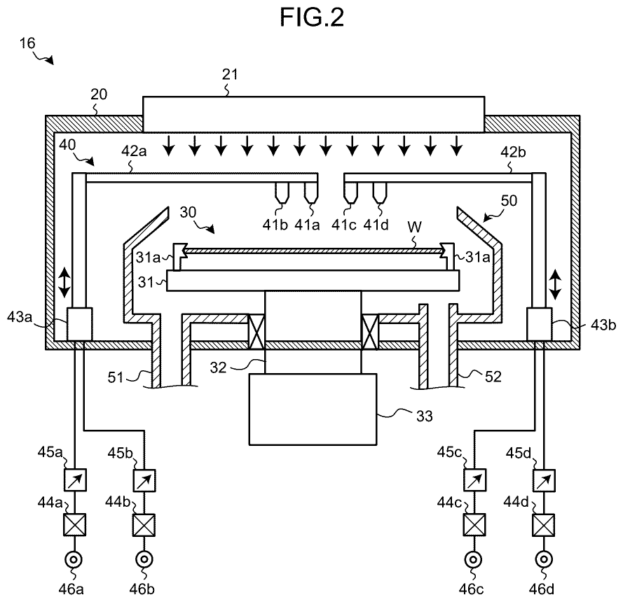

Next, a configuration of a processing unit 16 will be explained with reference to FIG. 2. FIG. 2 is a schematic diagram that illustrates an example of a specific configuration of a processing unit 16 according to an embodiment. As illustrated in FIG. 2, the processing unit 16 includes a chamber 20, a substrate processing unit 30, a liquid supply unit 40, and a recovery cup 50.

The chamber 20 houses the substrate processing unit 30, the liquid supply unit 40, and the recovery cup 50. A FFU (Fan Filter Unit) 21 is provided on a ceiling part of the chamber 20. The FFU 21 forms a downflow in the chamber 20.

The substrate processing unit 30 includes a holding unit 31, a supporting unit 32, and a driving unit 33 and applies liquid processing to a placed wafer W. The holding unit 31 holds a wafer W horizontally. The supporting unit 32 is a member that extends in a vertical direction and is provided with a proximal part that is rotatably supported by the driving unit 33 and a distal part that supports the holding unit 31 horizontally. The driving unit 33 rotates the supporting unit 32 around a vertical axis.

Such a substrate processing unit 30 rotates the supporting unit 32 by using the driving unit 33, so as to rotate the holding unit 31 that is supported by the supporting unit 32 and thereby rotate a wafer W that is held by the holding unit 31.

A holding member 31a that holds a wafer W from a side surface thereof is provided on an upper surface of the holding unit 31 that is included in the substrate processing unit 30. A wafer W is held horizontally in a state where it is slightly separated from an upper surface of the holding unit 31 by such a holding member 31a. Additionally, a wafer W is heled by the holding unit 31 in a state where a surface where substrate processing is executed is directed upward.

The liquid supply unit 40 supplies a processing fluid to a wafer W. The liquid supply unit 40 includes nozzles 41a, 41b, an arm 42a that supports the nozzles 41a, 41b horizontally, and a turning/lifting mechanism 43a that turns and lifts the arm 42a. Furthermore, the liquid supply unit 40 includes nozzles 41c, 41d, an arm 42b that supports the nozzles 41c, 41d horizontally, and a turning/lifting mechanism 43b that turns and lifts the arm 42b.

The nozzle 41a is connected to a first supply unit 46a through a valve 44a and a flow rate regulator 45a. For example, a first processing liquid that is supplied from the first supply unit 46a is configured to include ethyl acetate, acetone, or acetonitrile as a solvent and to include trichloroisocyanuric acid (TCCA) as a solute. A concentration of trichloroisocyanuric acid in a first processing liquid is, for example, 0.01 wt % to 1.0 wt %.

The nozzle 41b is connected to a second supply unit 46b through a valve 44b and a flow rate regulator 45b. A second processing liquid that is supplied from the second supply unit 46b is, for example, an aqueous solution of TMAH (tetramethylammonium hydroxide) or choline.

The nozzle 41c is connected to a third supply unit 46c through a valve 44c and a flow rate regulator 45c. A third processing liquid that is supplied from the third supply unit 46c is, for example, ethyl acetate, acetone, or acetonitrile.

The nozzle 41d is connected to a fourth supply unit 46d through a valve 44d and a flow rate regulator 45d. A rinsing liquid that is supplied from the fourth supply unit 46d is, for example, DIW (DeIonized Water: deionized water).

A first processing liquid that is supplied from the first supply unit 46a is discharged from the nozzle 41a. A second processing liquid that is supplied from the second supply unit 46b is discharged from the nozzle 41b. A third processing liquid that is supplied from the third supply unit 46c is discharged from the nozzle 41c. A rinsing liquid that is supplied from the fourth supply unit 46d is discharged from the nozzle 41d.

The recovery cup 50 is located so as to surround the holding unit 31 and traps a processing liquid that is scattered from a wafer W by rotation of the holding unit 31. A drain port 51 is formed on a bottom part of the recovery cup 50 and a processing liquid that is trapped by the recovery cup 50 is discharged from such a drain port 51 to an outside of the processing unit 16. Furthermore, an exhaust port 52 that discharges a gas that is supplied from the FFU 21 to an outside of the processing unit 16 is formed on a bottom part of the recovery cup 50.

### Substrate Processing

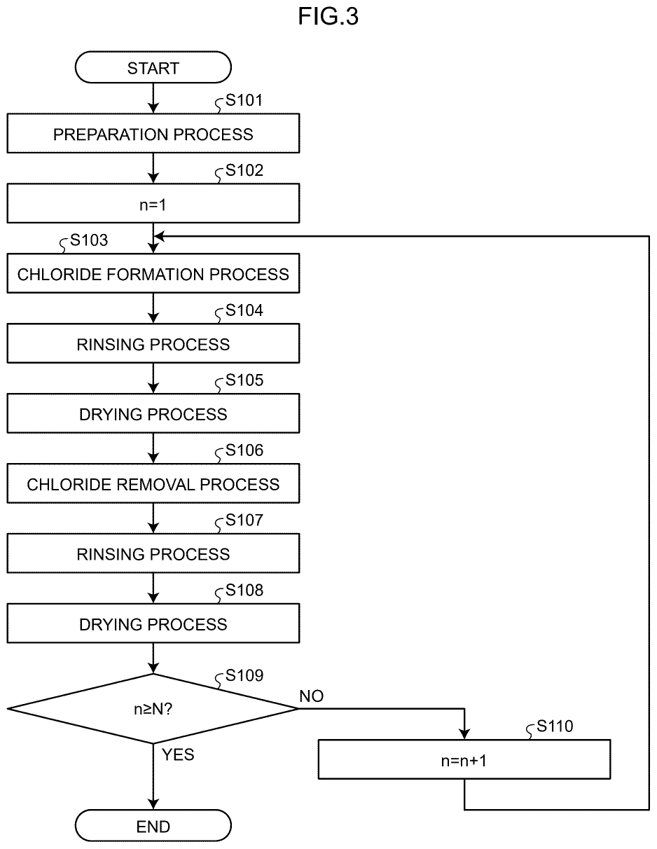

Next, a detail(s) of substrate processing according to an embodiment will be explained with reference to FIG. 3 to FIG. 7. FIG. 3 is a flowchart that illustrates an example of a procedure of substrate processing according to an embodiment.

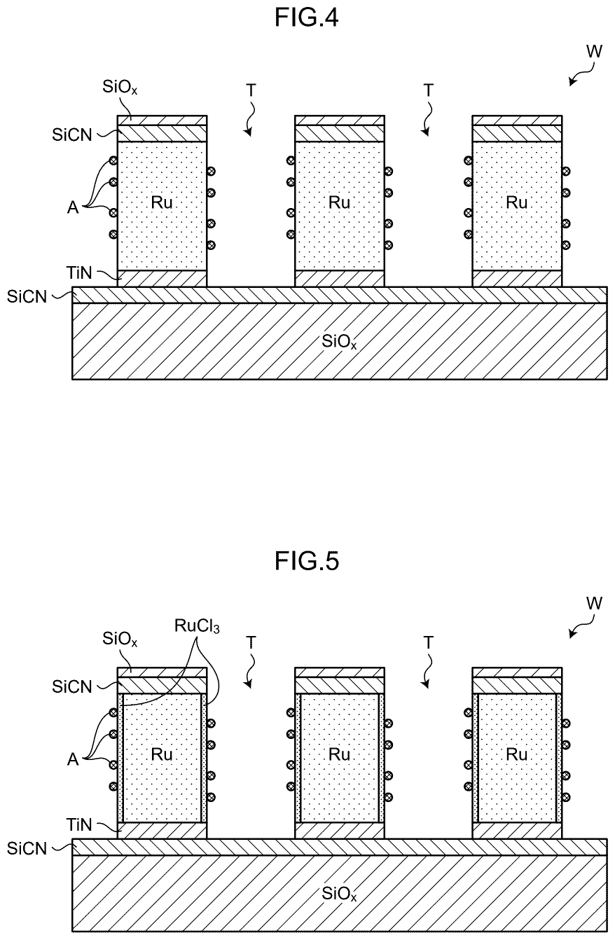

As illustrated in FIG. 3, in substrate processing according to an embodiment, first, a preparation process is executed (step S101). In such a preparation process, for example, a wafer W with a surface that is provided in a state as illustrated in FIG. 4 is prepared. FIG. 4 is an enlarged cross-sectional diagram that illustrates an example of a state of a surface of a wafer W after a preparation process according to an embodiment.

For a state as illustrated in FIG. 4, first, thin films are film-formed on a surface of a wafer W, in order of a SiOₓ (silicon oxide) film, a SiCN (silicon carbonitride) film, a TiN (titanium nitride) film, a Ru (ruthenium) film, a SiCN film, and a SiOₓ film by using a publicly-known film formation technique.

An Ru film is an example of a metallic film. Additionally, in the present disclosure, a Ru film is not limited to a case where it is composed of ruthenium only as long as at least ruthenium is included therein.

Then, a single or multiple (multiple in a figure) recessed part(s) T is/are formed on a surface of a wafer W by using a publicly-known etching technique. Such a recessed part T is formed so as to penetrate from a SiOₓ film as a top layer to a TiN film. Thereby, a preparation process according to an embodiment is ended.

Then, for a wafer W where a preparation process is ended, a plurality of residues A are attached to a side surface of a Ru film that is exposed at a recessed part T, as illustrated in FIG. 4. Such a residue A is produced in, for example, an etching process that forms a recessed part T, and is a Ru oxide and a Ru chloride, etc. Substrate processing as explained below is executed where a principal purpose thereof is to remove such a plurality of residues A.

An explanation for FIG. 3 is returned to. Following a preparation process as explained above, a controller 18 (see FIG. 1) set a counter n for counting a number of times that substrate processing is executed at 1 (step S102).

In substrate processing according to an embodiment, then, a chloride formation process is executed (step S103). In such a chloride formation process, the controller 18 holds a wafer W by a holding unit 31 (see FIG. 2), and subsequently, controls a liquid supply unit 40 (see FIG. 2), etc., so as to supply a first processing liquid from a nozzle 41a (see FIG. 2) to a rotating wafer W.

Thereby, as illustrated in FIG. 5, a film of a Ru chloride RuCl₃ is formed on a surface of a Ru film that is exposed at a recessed part T. FIG. 5 is an enlarged cross-sectional diagram that illustrates an example of a state of a surface of a wafer W after a chloride formation process according to an embodiment.

A Ru chloride RuCl₃ is an example of a metal chloride. Such a film of a Ru chloride RuCl₃ has a thickness in the order of atomic layers where such a thickness is, for example, 1 nm or less.

Thus, in an embodiment, trichloroisocyanuric acid that is included in a first processing liquid reacts with ruthenium in a Ru film, so that a film of a Ru chloride RuCl₃ in the order of atomic layers is formed on a surface of such a Ru film.

Furthermore, in an embodiment, it is preferable for a first processing liquid to contain 0.01 to 1.0 wt % of trichloroisocyanuric acid. Thereby, it is possible to form a film of an Ru chloride RuCl₃ in the order of atomic layers on a surface of a Ru film efficiently.

Furthermore, in an embodiment, it is preferable to use ethyl acetate, acetone, or acetonitrile that is an organic solvent as a solvent of a first processing liquid. Thus, not water but an organic solvent is used for a solvent of a first processing liquid, so that it is possible to reduce or prevent unexpected water etching of a surface of a Ru film with a film of an Ru chloride RuCl₃ that is formed thereon.

An explanation for FIG. 3 is returned to. In substrate processing according to an embodiment, then, a rinsing process is executed (step S104).

In such a rinsing process, the controller 18 controls the liquid supply unit 40, etc., so as to supply ethyl acetate, acetone, or acetonitrile that is a third processing liquid from a nozzle 41c (see FIG. 2) to a wafer W that rotates and is wet with a first processing liquid. Thereby, a first processing liquid is removed from a surface of a wafer W, so that reaction between a Ru film and such a first processing liquid is stopped.

Then, in an embodiment, it is preferable to use ethyl acetate, acetone, or acetonitrile that is an organic solvent as a third processing liquid that is used for a rinsing process. Thus, not water but an organic solvent is used for a rinsing process, so that it is possible to reduce or prevent unexpected water etching of a surface of a Ru film with a film of a Ru chloride RuCl₃ that is formed thereon.

Furthermore, in an embodiment, it is more preferable to use ethyl acetate as a third processing liquid. Thereby, it is possible to execute a drying process as described later at a preferable drying rate.

In substrate processing according to an embodiment, then, a drying process is executed (step S105). In such a drying process, the controller 18 controls a substrate processing unit 30 and the liquid supply unit 40, etc., so as to stop supply of a third processing liquid from the nozzle 41c and rotate a wafer W at a high speed in such a manner that such a third processing liquid is shaken off. Thereby, a drying process is applied to a wafer W.

In substrate processing according to an embodiment, then, a chloride removal process is executed (step S106). In such a chloride removal process, the controller 18 controls the substrate processing unit 30 and the liquid supply unit 40, etc., so as to supply an aqueous solution of TMAH or choline that is a second processing liquid from a nozzle 41b (see FIG. 2) to a rotating wafer W.

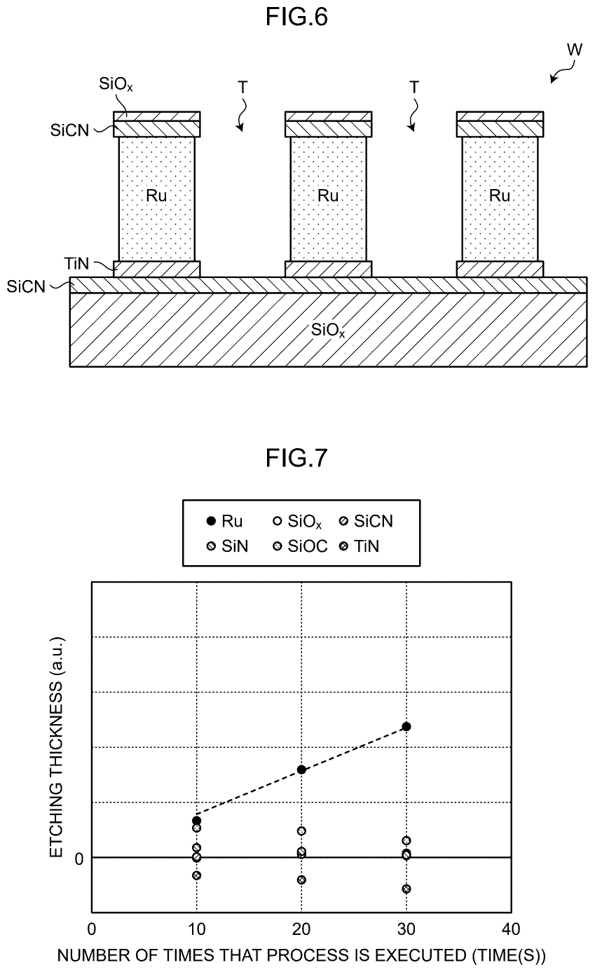

Thereby, as illustrated in FIG. 6, a film of a Ru chloride RuCl₃ (see FIG. 5) that is formed on a surface of a Ru film is removed. FIG. 6 is an enlarged cross-sectional diagram that illustrates an example of a state of a surface of a wafer W after a chloride removal process according to an embodiment. Additionally, as illustrated in FIG. 6, a third processing liquid does not etch a Ru film per se.

As has been explained above, in substrate processing according to an embodiment, it is possible to execute atomic layer etching of a Ru film efficiently by using a first processing liquid and a third processing liquid.

Furthermore, in an embodiment, a plurality of residues A (see FIG. 5) that are attached to a film of a Ru chloride RuCl₃ are removed from a Ru film together with a film of a Ru chloride RuCl₃. Thereby, it is possible to remove a plurality of residues A efficiently.

Furthermore, in an embodiment, a film thickness of a Ru chloride RuCl₃ is provided in the order of atomic layers, so that it is possible to minimize damage to a Ru film and it is possible to reduce or prevent increasing of a surface roughness of such a Ru film that is caused by an etching process.

Furthermore, in an embodiment, it is preferable to use an aqueous solution of TMAH or choline as a third processing liquid. Thus, an aqueous solution of TMAH or choline that contains no metal element is used as a third processing liquid that removes a film of a Ru chloride RuCl₃, so that it is possible to reduce or prevent contaminating of a wafer W, etc., with a metal element.

An explanation for FIG. 3 is returned to. In substrate processing according to an embodiment, following a chloride removal process as explained above, a rinsing process is executed (step S107).

In such a rinsing process, the controller 18 controls the liquid supply unit 40, etc., so as to supply DIW that is a rinsing liquid from a nozzle 41d (see FIG. 2) to a wafer W that rotates and is wet with a second processing liquid. Thereby, a second processing liquid is removed from a surface of a wafer W.

In substrate processing according to an embodiment, then, a drying process is executed (step S108). In such a drying process, the controller 18 controls the substrate processing unit 30 and the liquid supply unit 40, etc., so as to stop of supply of a rinsing liquid from the nozzle 41d and rotate a wafer W at a high speed in such a manner that such a rinsing liquid is shaken off. Thereby, a drying process is applied to a wafer W.

In substrate processing according to an embodiment, then, the controller 18 determines whether or not a counter n that indicates a number of times that substrate processing is executed is a predetermined number of times N or greater (step S109).

Then, in a case where a counter n is a predetermined number of times N or greater (step S109, Yes), a series of substrate processing is ended. On the other hand, in a case where a counter n is not a predetermined number of times N or greater (step S109, No), the controller 18 increments a counter n that indicates a number of times that substrate processing is executed (step S110) and returns to a process at step S103.

Thus, in an embodiment, it is preferable to execute processes at steps S103 to S108 sequentially and repeatedly. Thereby, it is possible to etch a surface of a Ru film so as to provide a desired thickness accurately.

Furthermore, in an embodiment, it is preferable to locate a Ru film on a film of at least one kind of SiOₓ, SiCN, SiN (silicon nitride), SiOC (silicon oxycarbide), and TiN. Thereby, it is possible for substrate processing according to an embodiment to reduce or prevent etching of a film of at least one kind of SiOₓ, SiCN, SiN, SiOC, and TiN together with a Ru film.

FIG. 7 is a diagram that illustrates a relationship between a number of times that a process is executed and etching thicknesses of various types of materials for substrate processing according to an embodiment. Additionally, in an example of FIG. 7, a processing liquid where 1.0 wt % of trichloroisocyanuric acid is added to ethyl acetate is used as a first processing liquid, ethyl acetate is used as a second processing liquid, and 1 mol/L of TMAH is used as a third processing liquid. Furthermore, in an example of FIG. 7, all of temperatures of respective processing liquids are a room temperature.

As illustrated in FIG. 7, in substrate processing according to an embodiment, an amount of etching of Ru is linearly increased with increasing a number of times that a process is executed. On the other hand, it is found that an amount of etching of SiOₓ, SiCN, SiN, SiOC, and TiN is little increased even when a number of times that a process is executed is increased.

That is, in substrate processing according to an embodiment, it is possible to etch only Ru selectively among Ru, SiOₓ, SiCN, SiN, SiOC, and TiN. Therefore, according to an embodiment, it is possible to etch only a Ru film selectively in a device structure as illustrated in FIG. 4, so that it is possible to maintain such a device structure well.

A substrate processing method according to an embodiment includes a forming step (step S103) and a removing step (step S106). The forming step (step S103) treats a surface of a metallic film (a Ru film) that includes ruthenium with a first processing liquid so as to form a metal chloride (a Ru chloride RuCl₃) on a surface of the metallic film (the Ru film). The removing step (step S106) removes the metal chloride (the Ru chloride RuCl₃) with a second processing liquid. Thereby, it is possible to execute an atomic layer etching of a Ru film efficiently.

Furthermore, in the substrate processing method according to an embodiment, the first processing liquid contains 0.01 to 1.0 wt % of trichloroisocyanuric acid. Thereby, it is possible to form a film of a Ru chloride RuCl₃ in the order of atomic layers on a surface of a Ru film efficiently.

Furthermore, in the substrate processing method according to an embodiment, a solvent of the first processing liquid is ethyl acetate, acetone, or acetonitrile. Thereby, it is possible to reduce or prevent unexpected water etching of a surface of a Ru film with a film of a Ru chloride RuCl₃ that is formed thereon.

Furthermore, in the substrate processing method according to an embodiment, the metallic film (the Ru film) is located on a film of at least one kind of SiOₓ, SiCN, SiN, SiOC, and TiN. Thereby, it is possible to maintain a device structure on a wafer W well.

Furthermore, in the substrate processing method according to an embodiment, the second processing liquid is an aqueous solution of TMAH or choline. Thereby, it is possible to reduce or prevent contaminating of a wafer W, etc., with a metal element.

Furthermore, the substrate processing method according to an embodiment further includes a rinsing step (step S104) and a drying step (step S105). The rinsing step (step S104) rinses a surface of the metal chloride (the Ru chloride RuCl₃) with a third processing liquid and is executed after the forming step (step S103). The drying step (step S105) dries a surface of the metal chloride (the Ru chloride RuCl₃) and is executed after the rinsing step (step S104). Thereby, it is possible to reduce or prevent forming of a Ru chloride RuCl₃ with an excessive film thickness on a surface of a Ru film.

Furthermore, in the substrate processing method according to an embodiment, the third processing liquid is ethyl acetate, acetone, or acetonitrile. Thereby, it is possible to reduce or prevent unexpected water etching of a surface of a Ru film with a film of a Ru chloride RuCl₃ that is formed thereon.

Furthermore, in the substrate processing method according to an embodiment, the forming step (step S103) and the removing step (step S106) are executed sequentially and repeatedly. Thereby, it is possible to etch a surface of a Ru film so as to provide a desired thickness accurately.

Furthermore, in the substrate processing method according to an embodiment, a film thickness of the metal chloride (the Ru chloride RuCl₃) is 1 nm or less. Thereby, it is possible to minimize damage to a Ru film and it is possible to reduce or prevent increasing of a surface roughness of such a Ru film.

Furthermore, a substrate processing apparatus according to an embodiment includes a holding unit 31, a liquid supply unit 40, and a controller 18. The holding unit 31 holds and rotates a substrate (a wafer W) where a metallic film (a Ru film) that includes ruthenium is formed. The liquid supply unit 40 supplies a processing liquid to the substrate (the wafer W) that is held by the holding unit 31. The controller 18 controls each unit. Furthermore, the controller 18 treats a surface of the metallic film (the Ru film) with a first processing liquid so as to form a metal chloride (a Ru chloride RuCl₃) on a surface of the metallic film (the Ru film), and removes the metal chloride (the Ru chloride RuCl₃) with a second processing liquid. Thereby, it is possible to execute atomic layer etching of a Ru film efficiently.

Although an embodiment(s) of the present disclosure has/have been explained above, the present disclosure is not limited to an embodiment(s) as described above and various modifications are possible without departing from an essence thereof. For example, although an example where a technique(s) of the present disclosure is/are applied to a wafer W with a surface structure as illustrated in FIG. 4 has been illustrated in an embodiment(s) as described above, the present disclosure is not limited to such an example.

For example, a technique(s) of the present disclosure may be applied to a Ru film that is embedded in a recessed part that is formed on a wafer W, and that is provided with an exposed upper surface. Thereby, it is also possible to execute atomic layer etching of a Ru film efficiently.

It should be considered that an embodiment(s) as disclosed herein is/are not limitative but is/are illustrative in all aspects thereof. In fact, it is possible to implement an embodiment(s) as described above in a variety of modes. Furthermore, an embodiment(s) as described above may be omitted, substituted, and/or modified in various modes without departing from the appended claim(s) and an essence thereof.

An embodiment provides a technique that is capable of executing atomic layer etching for a metallic film that includes ruthenium efficiently.

A substrate processing method according to an aspect of an embodiment includes a step of treating a surface of a metallic film that includes ruthenium with a first processing liquid so as to form a metal chloride on a surface of the metallic film, and a step of removing the metal chloride with a second processing liquid.

According to an embodiment, it is possible to execute atomic layer etching for a metallic film that includes ruthenium efficiently. Additionally, an effect as described herein is not necessarily limitative and may be any effect as described in the present disclosure.

Appendix (1). A substrate processing method, including:
a step of treating a surface of a metallic film that includes ruthenium with a first processing liquid so as to form a metal chloride on a surface of the metallic film; and
a step of removing the metal chloride with a second processing liquid.

Appendix (2). The substrate processing method according to appendix (1), wherein
the first processing liquid contains 0.01 to 1.0 wt % of trichloroisocyanuric acid.

Appendix (3). The substrate processing method according to appendix (2), wherein
a solvent of the first processing liquid is ethyl acetate, acetone, or acetonitrile.

Appendix (4). The substrate processing method according to any one of appendices (1) to (3), wherein
the metallic film is located on a film of at least one kind of SiOₓ, SiCN, SiN, SiOC, and TiN.

Appendix (5). The substrate processing method according to any one of appendices (1) to (3), wherein
the second processing liquid is an aqueous solution of TMAH or choline.

Appendix (6). The substrate processing method according to any one of appendices (1) to (3), further including:
a step of rinsing a surface of the metal chloride with a third processing liquid that is executed after the step of forming; and
a step of drying a surface of the metal chloride that is executed after the step of rinsing.

Appendix (7). The substrate processing method according to appendix (6), wherein
the third processing liquid is ethyl acetate, acetone, or acetonitrile.

Appendix (8). The substrate processing method according to any one of appendices (1) to (3), wherein
the step of forming and the step of removing are executed sequentially and repeatedly.

Appendix (9). The substrate processing method according to any one of appendices (1) to (3), wherein
a film thickness of the metal chloride is 1 nm or less.

Appendix (10). A substrate processing apparatus, including:
a holding unit that holds and rotates a substrate where a metallic film that includes ruthenium is formed;
a liquid supply unit that supplies a processing liquid to the substrate that is held by the holding unit; and
a controller that controls each unit, wherein
the controller treats a surface of the metallic film with a first processing liquid so as to form a metal chloride on a surface of the metallic film, and removes the metal chloride with a second processing liquid.

What is claimed is:

1. A substrate processing method, including:
treating a surface of a metallic film that includes ruthenium with a first processing liquid to form a metal chloride on a surface of the metallic film; and
removing the metal chloride with a second processing liquid.

2. The substrate processing method according to claim 1, wherein
the first processing liquid contains 0.01 to 1.0 wt % of trichloroisocyanuric acid.

3. The substrate processing method according to claim 2, wherein
a solvent of the first processing liquid is ethyl acetate, acetone, or acetonitrile.

4. The substrate processing method according to claim 1, wherein
the metallic film is located on a film of at least one kind of SiOₓ, SiCN, SiN, SiOC, and TiN.

5. The substrate processing method according to claim 1, wherein
the second processing liquid is an aqueous solution of TMAH or choline.

6. The substrate processing method according to claim 1, further including:
rinsing a surface of the metal chloride with a third processing liquid after the forming; and
drying a surface of the metal chloride after the rinsing.

7. The substrate processing method according to claim 6, wherein
the third processing liquid is ethyl acetate, acetone, or acetonitrile.

8. The substrate processing method according to claim 1, wherein
the forming and the removing are executed sequentially and repeatedly.

9. The substrate processing method according to claim 1, wherein
a film thickness of the metal chloride is 1 nm or less.

10. A substrate processing apparatus, comprising:
a holding unit that holds and rotates a substrate where a metallic film that includes ruthenium is formed;
a liquid supply unit that supplies a processing liquid to the substrate that is held by the holding unit; and
a controller that controls at least the holding unit and the liquid supply unit, wherein
the controller is configured to treat a surface of the metallic film with a first processing liquid to form a metal chloride on a surface of the metallic film, and remove the metal chloride with a second processing liquid.
